(19) United States
(12) Patent Application Publication
(10) Pub. No.: US 2012/0048364 A1
(43) Pub. Date: Mar. 1, 2012

(54) FRONT SIDE SUBSTRATE OF PHOTOVOLTAIC PANEL, PHOTOVOLTAIC PANEL AND USE OF A SUBSTRATE FOR A FRONT SIDE OF A PHOTOVOLTAIC PANEL

(75) Inventors: Stephane Auvray, Suresnes (FR); Thien Hai Dao, Hanoi (VN); Selvaraj Venkataraj, Tamilnadu (IN)

(73) Assignee: SAINT-GOBAIN GLASS FRANCE, Courbevoie (FR)

(21) Appl. No.: 13/132,824

(22) PCT Filed: Dec. 3, 2009
(86) PCT No.: PCT/FR2009/052403

§ 371 Date: Nov. 10, 2011

(30) Foreign Application Priority Data
Dec. 4, 2008 (FR) 0858260

(51) Int. Cl. H01L 31/0216; B05D 5/12; H01L 31/18; B32B 15/04

(52) U.S. Cl. 136/256; 428/469; 427/74

(57) ABSTRACT

A photovoltaic panel has an absorbent photovoltaic material, particularly based on cadmium, said panel including a front side substrate, particularly a transparent glass substrate with a transparent electrode coating, where the antireflection coating placed above the metal functional layer opposite the substrate has a single antireflection layer, based on mixed zinc tin oxide over its whole thickness, or where the antireflection coating placed above the metal functional layer opposite the substrate has at least two antireflection layers including, on the one hand, an antireflection layer which is closer to the functional layer and is based on mixed zinc tin oxide over its whole thickness and, on the other, an antireflection layer which is further from the functional layer and is not based on mixed zinc tin oxide over its whole thickness.

The invention relates to a front side substrate of a photovoltaic panel, particularly a transparent glass substrate.

In a photovoltaic panel, a photovoltaic system containing a photovoltaic material which produces electrical energy under the effect of incident radiation is positioned between a rear side substrate and a front side substrate, this front side substrate being the first substrate through which the incident radiation passes before it reaches the photovoltaic material.

In the photovoltaic panel, the front side substrate commonly comprises, below a main surface facing the photovoltaic material, a transparent electrode coating in electrical contact with the photovoltaic material placed below when considering that the main direction of arrival of the incident radiation is from above.

This front side electrode coating thus constitutes for example the negative terminal of the photovoltaic panel.

Obviously, the photovoltaic panel also comprises, in the direction of the rear side substrate, an electrode coating which thereby constitutes the positive terminal of the photovoltaic panel, but in general the electrode coating of the rear side substrate is not transparent.

In the context of the present invention, “photovoltaic panel” means any set of constituents generating the production of an electric current between its electrodes by conversion of solar radiation, regardless of the dimensions of this assembly and regardless of the voltage and current produced and, in particular, that this set of constituents does or does not have one (or more) internal electrical connections (in series and/or in parallel). The concept of “photovoltaic panel” in the context of the present invention is therefore equivalent here to that of “photovoltaic module” or even “photovoltaic cell”.

The material commonly used for the transparent electrode coating of the front side substrate is generally a material based on a transparent conducting oxide (TCO), like for example a material based on indium tin oxide (ITO), or based on zinc oxide doped with aluminium (ZnO:Al) or doped with boron (ZnO:B), or even based on tin oxide doped with fluorine (SnO₂:F).

These materials are deposited chemically, as for example by chemical vapour deposition (“CVD”), optionally by plasma-enhanced chemical vapour deposition (“PECVD”), as for example by vacuum deposition by cathode sputtering, optionally enhanced by a magnetic field (i.e. magnetron sputtering).

However, to obtain the desired electrical conduction, or rather the desired low resistance, the electrode coating made from a TCO-based material must be deposited in a relatively high physical thickness, on the order of 500 to 1,000 nm and even sometimes more, which is expensive considering the cost of these materials when deposited in layers of this thickness.

When the deposition method requires a heat input, this further increases the production cost.

Another major drawback of the electrode coatings made from a TCO-based material resides in the fact that for a selected material, its physical thickness is always a compromise between the electrical conduction finally obtained and the transparency finally obtained, because the higher the physical thickness, the higher the conductivity but the lower the transparency, and vice versa, the lower the physical thickness, the greater the transparency but the lower the conductivity.

It is therefore not possible, with the electrode coatings made from a TCO-based material, to optimize the conductivity of the electrode coating and its transparency independently.

The prior art contains the U.S. Pat. No. 6,169,246, which relates to a photovoltaic cell containing an absorbent photovoltaic material based on cadmium, said cell comprising a transparent glass front side substrate comprising, on a main surface, a transparent electrode coating consisting of a transparent conducting oxide TCO.

According to this document, below the TCO electrode coating and above the photovoltaic material, a buffer layer of a zinc stannate is inserted, said layer therefore not being part either of the TCO electrode coating, or of the photovoltaic material. This layer also has the drawback of being very difficult to deposit by magnetron sputtering techniques, because the target incorporating this material is relatively non-conducting. The use of this type of insulating target in a magnetron “coater” generates a large number of electric arcs during the sputtering, causing numerous defects in the deposited layer.

The prior art contains from the international patent application No. WO 01/43204 a method for fabricating a photovoltaic panel in which the transparent electrode coating is not made from a TCO-based material but consists of a stack of thin layers deposited on a main face of the front side substrate, this coating comprising at least one metal functional layer, particularly based on silver, and at least two antireflection coatings, said antireflection coatings, each comprising at least one antireflection layer, said functional layer being placed between the two antireflection coatings.

This method is characterized in that it provides for at least one highly refringent layer of oxide or nitride to be deposited below the metal functional layer and above the photovoltaic material when considering the direction of the incident light which enters the panel from above.

The document describes an exemplary embodiment in which the two antireflection coatings on either side of the metal functional layer, the antireflection coating placed under the metal functional layer towards the substrate and the antireflection coating placed above the metal functional layer opposite the substrate each comprise at least one layer made from a highly refringent material, in this case from zinc oxide (ZnO) or from silicon nitride (Si₃N₄).

However, this solution can be further improved, in particular for methods for depositing photovoltaic coatings implemented at high temperatures, as is the case for cadmium-based photovoltaic coatings.

The present invention thereby consists, for a front side substrate of a photovoltaic panel, in defining particular conditions for the optical path of the front side electrode coating in order to obtain the desired photovoltaic panel efficiency according to the photovoltaic material selected, in particular when the latter requires a heat treatment for its application. (In the context of the present invention, “heat treatment” means that it is subjected to a temperature of at least 400° C. for at least one minute).

The invention, in a first approach, thus relates to a photovoltaic panel containing an absorbent photovoltaic material, particularly based on cadmium, said panel comprising a front side substrate, particularly a transparent glass substrate, comprising, on a main surface, a transparent electrode coating consisting of a stack of thin layers comprising at least one metal functional layer, particularly based on silver, and at least two antireflection coatings, said antireflection coatings each comprising at least one antireflection layer, said functional layer being placed between the two antireflection coatings, said antireflection coating placed above the metal functional layer opposite the substrate comprising a single antireflection layer, based on mixed zinc tin oxide over its whole thickness, this antireflection layer based on mixed zinc tin oxide having an optical thickness of between 1.5 and 4.5 times, inclusive, even between 1.5 and 3 times, inclusive, and preferably between 1.8 and 2.8 times, inclusive, the optical thickness of the antireflection coating placed below the metal functional layer.

The invention, in a second approach, thus relates to a photovoltaic panel containing an absorbent photovoltaic material, particularly based on cadmium, said panel comprising a front side substrate, particularly a transparent glass substrate, comprising, on a main surface, a transparent electrode coating consisting of a stack of thin layers comprising at least one metal functional layer, particularly based on silver, and at least two antireflection coatings, said antireflection coatings each comprising at least one antireflection layer, said functional layer being placed between the two antireflection coatings, the antireflection coating placed above the metal functional layer opposite the substrate comprising at least two antireflection layers including, on the one hand, an antireflection layer which is closer to the functional layer and is based on mixed zinc tin oxide over its whole thickness and, on the other, an antireflection layer which is further from the functional layer and is not based on mixed zinc tin oxide over its whole thickness, said antireflection layer(s), based on mixed zinc tin oxide over its whole thickness, this antireflection layer based on mixed zinc tin oxide having an optical thickness of between 0.1 and 6 times, or even 0.2 and 4 times, and in particular between 0.25 and 2.5 times, inclusive, the optical thickness of the antireflection coating placed below the metal functional layer.

For this second approach, said antireflection layer which is not based on mixed zinc tin oxide over its whole thickness (i.e. which does not comprise both Zn and Sn together) is preferably based on zinc oxide over its whole thickness. This layer may thus comprise zinc oxide and an element other than Sn or may comprise tin oxide and an element other than Zn.

For this second approach moreover, said antireflection layer(s), based on mixed zinc tin oxide over its whole thickness, has a total optical thickness representing between 2 and 50%, inclusive, of the optical thickness of the antireflection coating farthest from the substrate and particularly an optical thickness representing between 3 and 30%, inclusive, and in particular between 3.8% and 16.9%, inclusive, of the optical thickness of the antireflection coating farthest from the substrate.

However, in this second approach, it is also possible that said antireflection layer(s), based on mixed zinc tin oxide over its whole thickness, has a total optical thickness representing between 50 and 95%, inclusive, of the optical thickness of the antireflection coating farthest from the substrate and particularly an optical thickness representing between 70 and 90%, inclusive, of the optical thickness of the antireflection coating farthest from the substrate.

The two approaches thus propose a single solution for use in the overlying coating of the functional layer of a particular layer based on mixed zinc tin oxide over its whole thickness.

In fact, it has been observed that this layer had a particular capacity to make the stack of thin layers forming the particular transparent electrode coating resistant to a highly stressing heat treatment.

However, the thickness of this particular layer based on mixed zinc tin oxide over its whole thickness is not defined in the same way according to whether this layer is the only layer of the antireflection coating overlying the functional layer (between the functional layer and the photovoltaic material) or whether it is accompanied by another layer of another material in the antireflection coating overlying the functional layer, which explains the two approaches.

This antireflection layer, based on mixed zinc tin oxide over its whole thickness preferably has a resistivity ρ of between 2×10⁻⁴ Ω·cm and 10⁵ Ω·cm, inclusive, or even of between 0,1 and 10³ Ω·cm, inclusive.

In the context of the present invention, “coating” means that there may be a single layer or a plurality of layers of different materials in the coating.

In the context of the present invention, “antireflection layer” means that from the standpoint of its nature, the material is “non-metallic”, that is, it is not a metal. In the context of the invention, this term is not intended to introduce a limitation on the resistivity of the material, which may be that of a conductor (in general, ρ<10⁻³ Ω·cm), of an insulator (in general, ρ>10⁹ Ω·cm) or of a semiconductor (in general between the two preceding values).

The purpose of the coatings on either side of the metal functional layer is to make this metal functional layer “antireflecting”. This is why they are called “antireflection coatings”.

In fact, if the functional layer serves by itself to obtain the desired conductivity for the electrode coating, even with a low physical thickness (about 10 nm), it will strongly oppose the passage of light.

In the absence of such an antireflection system, the light transmission would then be too weak and the light reflection much too strong (in the visible and the near infrared because it concerns the production of a photovoltaic panel).

In the context of the present invention, the expression “optical path” assumes a specific meaning and is used to designate the sum of the various optical thicknesses of the various antireflection coatings underlying and overlying the metal functional layer of the interference filter thereby produced. It may be recalled that the optical thickness of a coating is equal to the product of the physical thickness of the material and its index when there is only a single layer in their coating, or of the sum of the products of the physical thickness of the material of each layer by its index when there are a plurality of layers (all the indices (or refractive indices) indicated in the present document are measured as usual at the wavelength of 550 nm).

The optical path according to the invention is, in absolute terms, a function of the physical thickness of the metal functional layer, but in actual fact, in the physical thickness range of the metal functional layer that serves to obtain the desired conductance, it so happens that it does not vary, so to speak. The solution according to the invention is thus suitable when the functional layer, for example based on silver, is a single layer, and has a physical thickness of between 5 and 20 nm, inclusive.

Furthermore, preferably, said antireflection coating placed above the metal functional layer has an optical thickness of between 0.4 and 0.6 times the maximum absorption wavelength λₘ of the photovoltaic material, inclusive, and preferably said antireflection coating placed above the metal functional layer has an optical thickness of between 0.4 and 0.6 times the maximum wavelength λ_{M} of the product of the absorption spectrum of the photovoltaic material and the solar spectrum, inclusive.

Moreover, preferably, said antireflection coating placed above the metal functional layer has an optical thickness of between 0.075 and 0.175 times the maximum absorption wavelength λₘ of the photovoltaic material, inclusive, and preferably said antireflection coating placed below the metal functional layer has an optical thickness of between 0.075 and 0.175 times the maximum wavelength λₘ of the product of the absorption spectrum of the photovoltaic material and the solar spectrum, inclusive.

Thus, according to the invention, an optimal optical path is defined according to the maximum absorption wavelength λₘ of the photovoltaic material, or preferably according to the maximum wavelength λₘ of the product of the absorption spectrum of the photovoltaic material and the solar spectrum, in order to obtain the best efficiency of the photovoltaic panel.

The solar spectrum referred to here is the AM 1.5 solar spectrum as defined by the ASTM standard.

Quite unexpectedly, the optical path of the electrode coating with a stack of monolayer functional thin layers according to the invention serves to obtain an improved photovoltaic panel efficiency, as well as an improved resistance to the stresses generated during the operation of the panel.

The stack of thin layers constituting the transparent electrode according to the invention is generally obtained by a succession of deposits produced by a vacuum technique, such as cathode sputtering, optionally magnetron sputtering.

In the context of the present invention, when it is stated that a layer or coating (comprising one or more layers) is deposited directly under or directly on another layer or coating, this means that no layer is inserted between these two layers or coatings.

In a particular alternative, the substrate comprises under the electrode coating a base antireflection layer having a low refractive index n₁₅ close to that of the substrate, said base antireflection layer preferably being based on silicon dioxide or based on aluminium oxide or based on a mixture of both.

Furthermore, this layer, which is dielectric, may constitute a chemical barrier layer to diffusion, and in particular to the diffusion of the sodium issuing from the substrate, thereby protecting the electrode coating, and more particularly the metal functional layer, particularly during an optional heat treatment, particularly tempering.

In the context of the invention, a dielectric layer is a layer that does not participate in the movement of electric charge (electric current) or the effect of whose participation in the movement of electric charge can be considered as nil in comparison with that of the other layers of the electrode coating.

Moreover, this basic antireflection layer preferably has a physical thickness of between 10 and 300 nm or between 25 and 200 nm and even more preferably between 35 and 120 nm.

The metal functional layer is preferably deposited in crystalline form on a thin dielectric layer which is also preferably crystalline (referred to in this case as “wetting layer” because it favours the appropriate crystal orientation of the metal layer deposited above).

This metal functional layer may be based on silver, copper or gold, and may optionally be doped with at least another of these elements.

The doping is commonly understood as a presence of the element in a quantity lower than 10 mol % of metal element in the layer, and in the present document the expression “based on” normally means a layer mainly containing the material, that is, containing at least 50 mol % of this material; the expression “based on” thus covers doping.

The stack of thin layers producing the electrode coating is preferably a functional monolayer coating, that is having a single functional layer; it cannot be a functional multilayer.

The functional layer is thus preferably deposited above or directly on a wetting layer based on oxide, particularly based on zinc oxide, optionally doped, optionally with aluminium.

The physical (or real) thickness of the wetting layer is preferably between 2 and 30 nm and even more preferably between 3 and 20 nm.

This wetting layer is dielectric and is a material which preferably has a resistivity ρ (defined by the product of the resistance per square of the layer and its thickness) such that 0.5 Ω·cm<ρ≦200 Ω·cm or such that 50 Ω·cm<ρ<200 Ω·cm.

The functional layer may moreover be placed directly on at least one underlying blocking coating and/or directly under at least one overlying blocking coating.

At least one blocking coating may be based on Ni or on Ti or is based on an Ni-based alloy, particularly based on an NiCr alloy.

In a particular alternative, the coating under the metal functional layer towards the substrate comprises a layer based on mixed oxide, and particularly based on a mixed zinc tin oxide or on a mixed indium tin oxide (ITO).

Furthermore, the coating under the metal functional layer towards the substrate and/or the coating above the metal functional layer may comprise a layer with a very high refractive index, particularly higher than or equal to 2, such as for example a layer based on silicon nitride, optionally doped, for example with aluminium or with zirconium.

In another particular alternative, the coating under the metal functional layer towards the substrate and/or the coating above the metal functional layer comprise(s) a layer with a very high refractive index, particularly higher than or equal to 2.35, like for example a layer based on titanium dioxide.

In a particular alternative, said electrode coating consists of a stack for architectural glazing, particularly a “temperable” stack for architectural glazing or one such stack “to be tempered”, and in particular a low-emissivity stack, particularly a “temperable” low-emissivity stack or one such stack “to be tempered”, this stack of thin layers having the features of the invention.

The present invention also relates to a substrate coated with a stack of thin layers for a photovoltaic panel according to the invention, particularly substrate for architectural glazing having the features of the invention, and in particular a “temperable” stack for architectural glazing or one such stack “to be tempered”, and in particular a low-emissivity stack, particularly a “temperable” low-emissivity stack or one such stack “to be tempered”, having the features of the invention.

This substrate also comprises a coating based on photovoltaic material above the electrode coating opposite the front side substrate for the fabrication of the photovoltaic panel according to the invention.

However, in the case in which the photovoltaic material is based on cadmium telluride deposited by heat treatment, if the electrode coating according to the invention is a stack of thin layers which is temperable, the substrate carrying this stack is however not tempered after this heat treatment in the case in which this treatment, owing to its temperature, is similar to a tempering heat treatment.

A preferred structure of a front side substrate according to the invention is thus of the type: substrate/(optional base antireflection layer)/electrode coating according to the invention/photovoltaic material, or even of the type: substrate/(optional base antireflection layer)/electrode coating according to the invention/photovoltaic material/electrode coating.

The present invention therefore also relates to this substrate for architectural glazing coated with a stack of thin layers having the features of the invention and which has undergone a heat treatment, and also this substrate for architectural glazing coated with a stack of thin layers having the features of the invention and having undergone a heat treatment, particularly of the type known from international patent application No. WO 2008/096089, the content of which is incorporated herewith.

The type of stack of thin layers according to the invention is known in the field of glazings for buildings or vehicles for obtaining reinforced thermal insulation glazing of the “low-emissivity” and/or “solar control” type.

The inventors have thus realized that certain stacks like those used for low-emissivity glazing in particular, were suitable for use for producing electrode coatings for photovoltaic panels, and in particular stacks known by the name of “temperable” stacks or stacks “to be tempered”, that is those used when the substrate carrying the stack is expected to undergo a tempering heat treatment.

The present invention thus also relates to the use of a stack of thin layers for architectural glazing having the features of the invention and particularly a stack of this type which is “temperable” or “to be tempered”, particularly a low-emissivity stack which is in particular “temperable” or “to be tempered”, to produce a front side substrate of a photovoltaic panel according to the invention, and also the use of a substrate coated with a stack of thin layers for producing a front side substrate of a photovoltaic panel according to the invention.

This stack or this substrate comprising the electrode coating may be a stack or a substrate for architectural glazing, particularly a substrate for architectural glazing, particularly a “temperable” stack or stack “to be tempered” for architectural glazing, and in particular a low-emissivity stack, particularly a “temperable” low-emissivity stack or one such stack “to be tempered”.

The present invention thus also relates to the use of this stack of thin layers which has undergone a heat treatment, and also the use of a stack of thin layers for architectural glazing having the features of the invention and having undergone a surface heat treatment of the type known from international patent application No. WO 2008/096089.

In the context of the present invention, “temperable” substrate means that the essential optical properties and the heat transfer properties (expressed by the resistance per square which is directly related to the emissivity) are preserved during the heat treatment.

Thus, it is possible to place, on the same building facade for example, glazing panels close to one another integrating tempered substrates and untempered substrates, all coated with the same stack, without the possibility of distinguishing between them by a simple visual observation of the colour in reflection and/or the light reflection/transmission.

For example, a stack or a substrate coated with a stack which has the following before/after heat treatment variations will be considered as temperable because these variations are not perceptible to the naked eye:
a small variation in light transmission (in the visible) ΔT_{L}, smaller than 3% or even 2%; and/or
a small variation in light reflection (in the visible) ΔR_{L}, smaller than 3% or even 2%; and/or
a small variation in colour (in the Lab system) ΔE=ΔE={square root over (((ΔL*)²+(Δa*)²+(Δb*)²))}, smaller than 3, or even 2.

In the context of the present invention, “temperable” substrate means that the optical and heat transfer properties of the coated substrate are acceptable after heat treatment, whereas they are not, or in any case not all of them, previously.

For example, a stack or a substrate coated with a stack which, after the heat treatment, has the following features, is considered as to be tempered in the context of the of present invention, whereas before the heat treatment, at least one of these features was not satisfied:
a high light transmission (in the visible) T_{L} of at least 65%, or even 70%, or even at least 75%; and/or
a low light absorption (in the visible; defined by 1-T_{L}-R_{L}) lower than 10%, or even lower than 8%, or even 5%; and/or
a resistance per square R at least as good as that of the conducting oxides commonly used, and in particular lower than 20Ω/□, or even lower than 15Ω/□, or even equal to or lower than 10 Ω/□.

Thus, the electrode coating must be transparent. Mounted on the substrate, it must therefore have an average light transmission between 300 and 1200 nm of at least 65%, or even 75%, and preferably even 85%, or even more particularly at least 90%.

If the front side substrate has undergone a heat treatment after the deposition of the thin layers and before its installation in the photovoltaic panel or for the application of the photovoltaic material, it is perfectly possible that, before this heat treatment, the substrate coated with the stack acting as an electrode coating is relatively non-transparent. Before this heat treatment, it may for example have a light transmission in the visible lower than 65%, or even lower than 50%.

The heat treatment may be applied instead of or in addition to a tempering of the substrate carrying the electrode coating, or be the result of a step in the fabrication of the photovoltaic panel.

Thus, in the context of the fabrication of the photovoltaic panel of which the photovoltaic coating, the one which performs the energy conversion between the light rays and the electrical energy, is based on cadmium, its fabrication process requires a hot deposition phase, in a temperature range of between 400 and 700° C. This heat input during the deposition of the photovoltaic coating on the stack forming the transparent front side electrode can cause physical chemical transformations in this photovoltaic coating, and also in the electrode coating, leading to a modification of the crystal structure of certain layers. This heat treatment is also more stressing than a tempering heat treatment because it generally lasts longer and/or is carried out at higher temperature.

It is therefore important for the electrode coating to be transparent before heat treatment and to be such that, after the heat treatment(s), it has an average light transmission between 300 and 1,200 nm (in the visible) of at least 65%, or even 75% and preferably even 85% or even more particularly at least 90%.

Furthermore, in the context of the invention, the stack does not, in absolute terms, have the best possible light transmission, but has the best possible light transmission in the context of the photovoltaic panel according to the invention and of its fabrication method.

All the layers of the electrode coating are preferably deposited by a vacuum deposition technique, but it is however not inconceivable for the first layer(s) of the stack to be deposited by another technique, for example by a thermal decomposition technique of the pyrolysis type or by CVD, optionally under vacuum, optionally plasma enhanced.

Advantageously, the electrode coating according to the invention with the stack of thin layers also has much higher mechanical strength than a TCO electrode coating. Thus, the service life of the photovoltaic panel can be increased.

Advantageously, the electrode coating according to the invention with a stack of thin layers also has an electrical resistance at least as good as that of the TCO conducting oxides commonly used. The resistance per square R, of the electrode according to the invention is between 1 and 20Ω/□, or even between 2 and 15Ω/□, for example about 5 to 8 Ω/□.

Advantageously, the electrode coating according to the invention with a stack of thin layers also has a light transmission in the visible at least as good as that of the TCO conducting oxides commonly used. The light transmission in the visible of the electrode coating according to the invention is between 50 and 98%, or even between 65 and 95%, for example about 70 to 90%.

The details and advantageous characteristics of the invention will appear from the following non-limiting examples, illustrated by means of the appended figures:

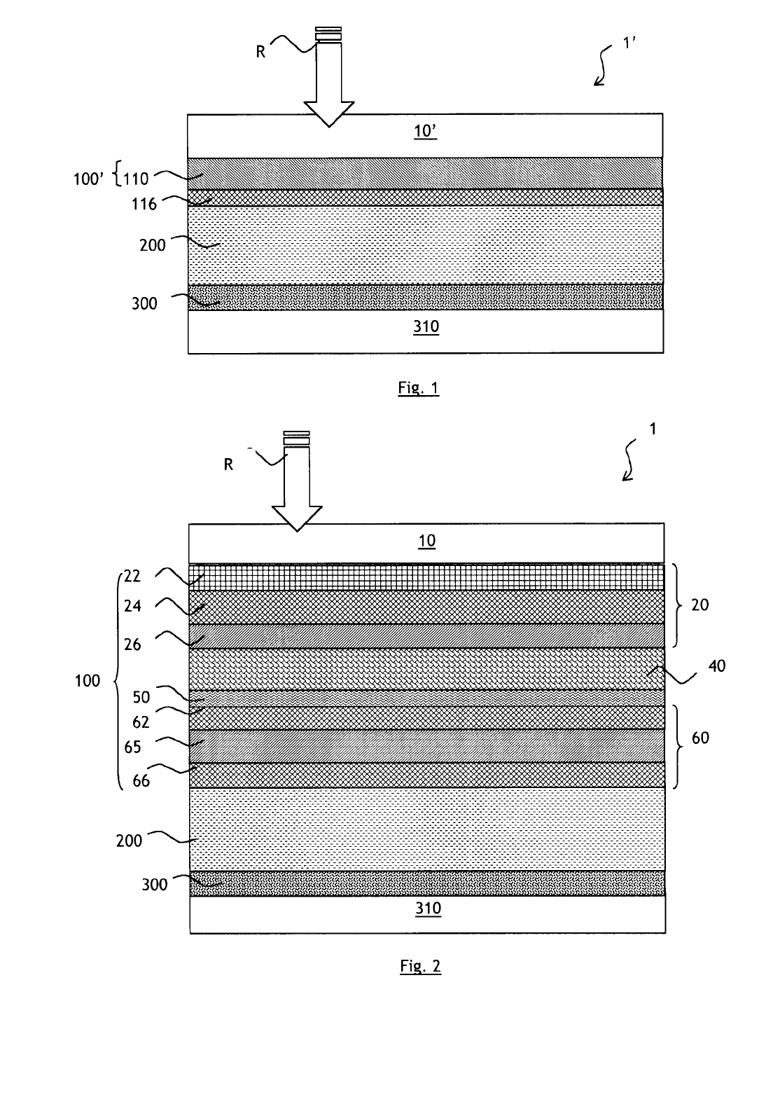

FIG. 1 shows a photovoltaic panel of the prior art with a front side substrate coated with a transparent conducting oxide electrode coating and a contact antireflection layer of mixed zinc tin oxide;

FIG. 2 shows a photovoltaic panel according to the invention with a front side substrate coated with an electrode coating consisting of a stack of monolayer functional thin layers and with an antireflection layer based on mixed zinc tin oxide;

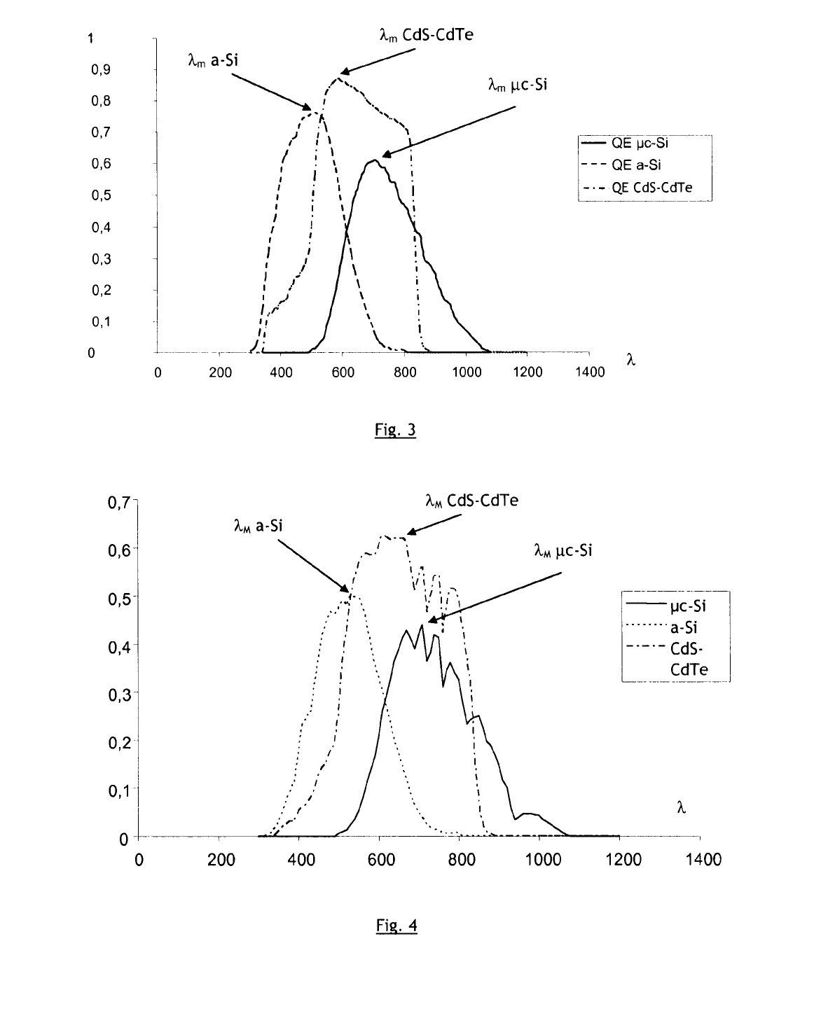

FIG. 3 shows the quantum efficiency curve of three photovoltaic materials;

FIG. 4 shows the real efficiency curve corresponding to the product of the absorption spectrum of these three photovoltaic materials and the solar spectrum; and

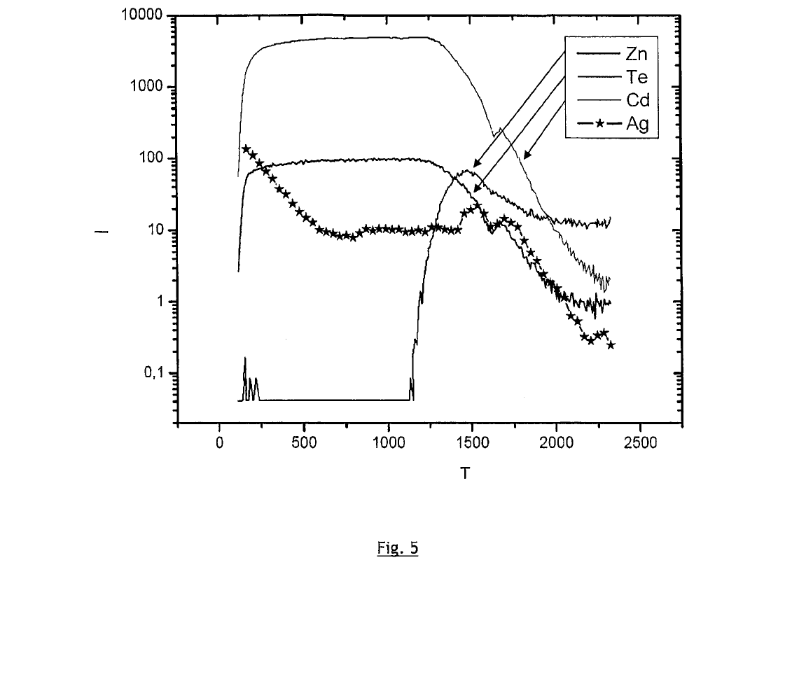

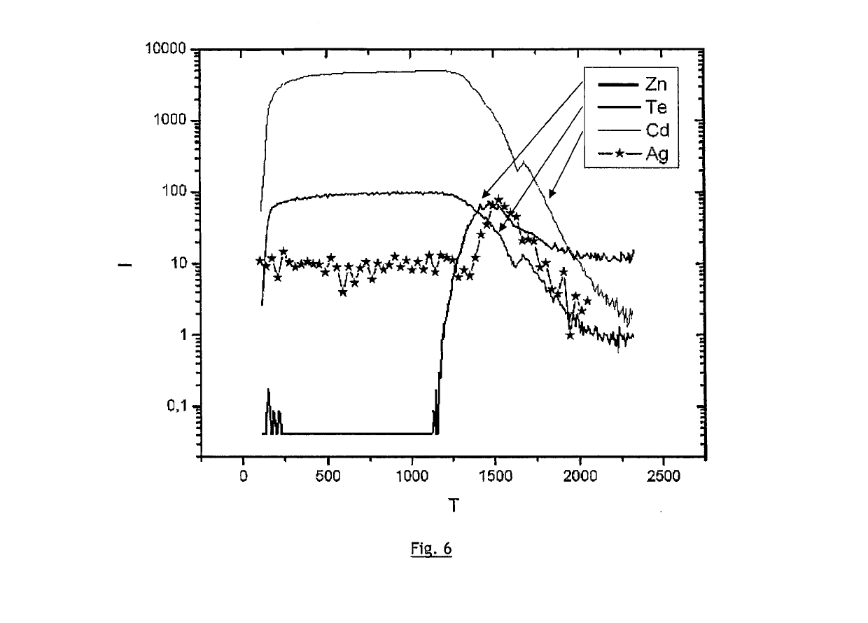

FIGS. 5 to 7 respectively show the TOF-SIMS analysis curves of examples 4, 5 and 9.

In FIGS. 1 and 2, the proportions between the thicknesses of the various coatings, layers and materials are not strictly respected in order to make them easier to read.

In FIGS. 5 to 8, all the elements analyzed are not illustrated, also in order to make the graphs easier to read.

FIG. 1 shows a photovoltaic panel 1′ comprising a front side substrate 10′ comprising, on a main surface a transparent electrode coating 100′, an absorbent photovoltaic coating 200 and a rear side substrate 310 comprising, on a main surface, an electrode coating 300, this photovoltaic coating 200 being placed between the two electrode coatings 100′, 300 and said transparent electrode coating 100′ consisting of a layer which conducts the current 110 and made from TCO.

It should be observed that a layer of resin, not shown here, is generally inserted between the electrode coating 300 and the substrate 310.

The front side substrate 10′ is placed in the photovoltaic panel in such a way that the front side substrate 10′ is the first substrate through which the incident radiation R passes before reaching the photovoltaic material 200.

A contact antireflection layer 116, based on mixed zinc tin oxide, generally made from zinc stannate Zn₂SnO₄, is inserted between the transparent electrode coating 100′ and the photovoltaic coating 200.

FIG. 2 shows a photovoltaic panel 1 identical to that of FIG. 1, except that a front side substrate 10 comprising, on a main surface, a transparent electrode coating 100 which conducts the current, i.e. a TCC (Transparent Conductive Coating), consisting of a stack of thin layers.

The photovoltaic panel 1 thus comprises, following the direction of the incident radiation R: a front side substrate 10 comprising, on a main surface, a transparent electrode coating 100, then an absorbent photovoltaic coating 200, an electrode coating 300 supported by a rear side substrate 310, said photovoltaic coating 200 being placed between the two electrode coatings 100, 300.

It should be observed that a layer of resin, not shown here, is generally inserted between the electrode coating 300 and the substrate 310.

The front side substrate 10 thus comprises, on a main surface, a transparent electrode coating 100, but here, unlike FIG. 1, this electrode coating 100 consists of a stack of thin layers comprising a metal functional layer 40, based on silver, and at least two antireflection coatings 20, 60, said coatings each comprising at least one thin antireflection layer 22, 24, 26; 62, 65, 66, said functional layer 40 being placed between the two antireflection coatings, one called underlying antireflection coating 20 located under the functional layer, towards the substrate (by turning around the substrate horizontally in comparison with that shown in FIG. 2), and the other called overlying antireflection coating 60 located above the functional layer, in the direction opposite the substrate.

The stack of thin layers constituting the transparent electrode coating 100 in FIG. 2 is a stack structure of the type such as a low-emissivity substrate, optionally temperable or to be tempered, functional monolayer, such as may be found on the market, for applications in the field of architectural glazings for buildings.

Two series of examples were prepared on the basis of the structure of the front side electrode coating illustrated:
for examples 1 to 3 in FIG. 1; and
for examples 4 to 10 in FIG. 2.

Furthermore, in all the examples below, the stack of thin layers was deposited on a substrate 10, 10′ of clear soda-lime glass having a thickness of 3 mm.

The electrode coating 100′ of the examples according to FIG. 1 is based on conducting aluminium-doped zinc oxide.

Each stack constituting an electrode coating 100 of the examples according to FIG. 2 consists of a stack of thin layers comprising a single functional layer 40, based on silver.

In all the examples, the photovoltaic material 200 is based on cadmium telluride. This material is deposited on the front side substrate 10, after the deposition of the electrode coating 100. The application of this photovoltaic material 200 based on cadmium telluride is carried out at a relatively high temperature, at least 400° C., and in general about 500° C. to 600° C.

The inventors have found that this heat treatment, even though similar to a tempering heat treatment, does not constitute a tempering heat treatment, even when carried out at high temperature close to the usual tempering temperatures (550° C. to 600° C.) and if it is carried out at this temperature when the substrate 10 has previously undergone a tempering heat treatment, while a “detempering” of the substrate 10 is observed during the deposition of the photovoltaic material 200 based on cadmium telluride. However, it is possible to preserve the tempered appearance of the substrate tempered prior to the deposition of the photovoltaic material, but only if the deposition of this material is carried out at a temperature below 500° C.

The photovoltaic material 200 could however also be based on microcrystalline silicon or based on amorphous silicon (that is non-crystalline).

The quantum efficiency QE of these materials is shown in FIG. 3.

It is recalled here that the quantum efficiency QE is, in a manner known per se, the expression of the probability (between 0 and 1) that an incident photon with a wavelength, on the x-axis in FIG. 3, is transformed into an electron-hole pair.

As may be observed in FIG. 3, the maximum absorption wavelength λₘ, that is, the wavelength at which the quantum efficiency is a maximum (that is the highest):
of amorphous silicon a-Si, λₘ a-Si, is 520 nm,
of microcrystalline silicon μc-Si, λₘ μc-Si, is 720 nm, and
of cadmium sulphide-cadmium telluride CdS—CdTe, λₘ CdS—CdTe, is 600 nm.

In a first approach, this maximum absorption wavelength λₘ is sufficient to define the optical thickness of the underlying 20 and overlying 60 antireflection coatings.

Table 1 below shows the preferred ranges of optical thicknesses in nm, for each coating 20, 60, as a function of these three materials.

TABLE 1

| Material | | a-Si | μc-Si | CdS-CdTe |
|---|---|---|---|---|
| Coating | λₘ/2 | 260 | 360 | 300 |
| 60 | 0.4λₘ | 208 | 288 | 240 |
| | 0.6λₘ | 312 | 432 | 360 |
| Coating | λₘ/8 | 65 | 90 | 75 |
| 20 | 0.075λₘ | 39 | 54 | 45 |
| | 0.175λₘ | 91 | 126 | 105 |

However, the optical definition of the stack can be improved by considering the quantum efficiency in order to obtain an improved real efficiency by convoluting this probability by the wavelength distribution of sunlight on the Earth's surface. Here, we use the standard solar spectrum AM1.5.

In this case, the antireflection coating 20 placed below the metal functional layer 40 towards a substrate has an optical thickness equal to about one-eighth of the maximum wavelength λ_{M} of the product of the absorption spectrum of the photovoltaic material and the solar spectrum, and the antireflection coating 60 placed above the metal functional layer 40 opposite the substrate has an optical thickness equal to about half of the maximum wavelength λ_{M}, of the product of the absorption spectrum of the photovoltaic material and the solar spectrum.

As may be observed in FIG. 4, the maximum wavelength λₘ of the product of the absorption spectrum of the photovoltaic material and the solar spectrum, that is, the wavelength at which the quantum efficiency is a maximum (that is the highest):
of amorphous silicon a-Si, λₘ a-Si, is 530 nm,
of microcrystalline silicon μc-Si, λₘ μc-Si, is 670 nm, et
of cadmium sulphide-cadmium telluride CdS—CdTe, λₘ CdS—CdTe, is 610 nm.

Table 2 below shows the preferred ranges of optical thicknesses in nm, for each coating 20, 60, as a function of these three materials.

TABLE 2

| Material | | a-Si | μc-Si | CdS-CdTe |
|---|---|---|---|---|
| Coating | λ_{M}/2 | 265 | 335 | 305 |
| 60 | 0.4λ_{M} | 212 | 268 | 244 |
| | 0.6λ_{M} | 318 | 402 | 366 |
| Coating | λ_{M}/8 | 66 | 84 | 76 |
| 20 | 0.075λ_{M} | 40 | 50 | 46 |
| | 0.175λ_{M} | 93 | 117 | 107 |

The photovoltaic material 200, for example based on amorphous silicon or crystalline or microcrystalline silicon or even on cadmium telluride or copper indium diselenide (CuInSe₂—CIS) or copper-indium-gallium-selenium, is located between two substrates: the front side substrate 10, 10′ via which the incident radian penetrates and the rear side substrate 310, 310′. This photovoltaic material consists of a layer of n-doped semiconductor material and a layer of p-doped semiconductor material, which produce the electric current. The electrode coatings 100, 300 inserted respectively between, on the one hand, the front side substrate 10, 10′ and the layer of n-doped semiconductor material and, on the other, between the layer of p-doped semiconductor material and the rear side substrate 310, 310′ completes the electrical structure.

The electrode coating 300 may be based on silver or aluminium or gold, or may also consist of a stack of thin layers comprising at least one metal functional layer and according to the present invention.

### FIRST SERIES OF EXAMPLES

### TCO

In a first series of examples, transparent electrode coatings made from TCO were deposited in order to have a reference.

Table 3 below summarizes the thicknesses of the layers of these electrode coatings for examples 1 to 3:

TABLE 3

| Layer/material | Ex. 1 | Ex. 2 | Ex. 3 |
|---|---|---|---|
| 116: SnZnO | — | — | 25 |
| 110: ZnO:Al | 600 | 1200 | 600 |

The resistivity p of the material of the TCO layer based on zinc oxide doped with aluminium (doped to 2% by weight of metal) was measured at 10⁻⁴ Ω·cm.

These three coatings were deposited on a clear glass substrate in order to constitute a front side of a photovoltaic panel, then a CdTe—CdS photovoltaic coating was deposited on the front side electrode coating, and finally a non-transparent second electrode coating, based on gold, was deposited to form the rear side electrode of the photovoltaic panel, as shown in FIG. 1 (but without a rear side substrate 310, nor a resin layer as sometimes observed).

The deposition of the CdTe—CdS photovoltaic coating was carried out at a temperature of about 550° C., for a time of about 2 min (total deposited thickness: about 6 μm). This is therefore highly stressing for the transparent front side electrode coating.

Table 4 below shows the main characteristics of the photovoltaic panels thus prepared on the basis of examples 1 to 3:

TABLE 4

| | Ex. 1 | Ex. 2 | Ex. 3 |
|---|---|---|---|
| Eta (%) | 2.2 | 6.27 | 7.5 |
| FF (%) | 34 | 54.2 | 56.7 |
| Jsc (mA/cm²) | 18.8 | 20.7 | 21.7 |
| Voc (V) | 0.34 | 0.56 | 0.61 |
| Rs (Ωcm²) | 12.8 | 8.8 | 8.2 |
| Rsh (kΩcm²) | 0.06 | 0.25 | 0.23 |

In this table:
Eta is the quantum efficiency of the photovoltaic panel, defined as the product FF×Jsc×Voc;
FF is the fill factor;
Jsc is the short-circuit current;
Voc is the open-circuit voltage;
Rs is the series resistance; and
Rsh is the shunt resistance, or short-circuit resistance.

It is thus possible to observe that the presence of the terminal layer 166 of mixed zinc tin oxide (which is more precisely for these three examples made from zinc stannate, having the formula Zn₂SnO₄) in the case of example 3, serves to obtain similar values to those obtained with example 2, whereas the thickness of the conducting oxide layer based on zinc oxide is reduced by half in the case of example 3.

### SECOND SERIES OF EXAMPLES

### TCC

Table 5 below summarizes the thicknesses of the layers of these electrode coatings for examples 4 to 10:

TABLE 5

| | Ex. 4 | Ex. 5 | Ex. 6 | Ex. 7 | Ex. 8 | Ex. 9 |
|---|---|---|---|---|---|---|
| 66: SnZnO | — | | — | — | 5 | 10 |
| 65: ZnO: Al | 135 | — | 135 | 120 | 130 | 120 |
| 62: SnZnO | — | 120 | 5 | 20 | 5 | 10 |
| 50: Ti | 1 | 1 | 1 | 1 | 1 | 1 |
| 40: Ag | 7 | 7 | 7 | 7 | 7 | 7 |
| 26: ZnO: Al | 7 | 7 | 7 | 7 | 7 | 7 |
| 24: SnZnO | 7 | 7 | 7 | 7 | 7 | 7 |
| 22: Si₃N₄: Al | 30 | 30 | 30 | 30 | 30 | 30 |

The structure of the stacks is as follows:
optionally an antireflection layer 22, which is a barrier layer to the alkali metals of the substrate and which is a dielectric layer based on silicon nitride doped to about 8% with aluminium, Si₃N₄:Al, with index n=1.99;
an antireflection layer 24 which is a smoothing layer based on mixed zinc tin oxide, having the formula Sn_{0,5}Zn_{0,5}O, and is a dielectric, with index n=1.99;
an antireflection layer 26 which is a wetting layer based on zinc oxide doped to about 2% with aluminium ZnO:Al, and is a dielectric, with index n=1.96;
optionally an underlying blocking layer (not shown in FIG. 2), for example based on Ti or based on an alloy of NiCr, could be placed directly under the functional layer 40, but is not provided here; this coating is generally required in the absence of a wetting layer 26, but is not necessarily indispensable;
the single functional layer 40, of silver, is thus placed here directly on the wetting coating 26;
an overlying blocking coating 50 based on Ti, or which could be based on an alloy of NiCr, placed directly on the functional layer 40; this coating is placed in metal form but may display partial oxidation in the photovoltaic panel;
an antireflection layer 62 which is an absorption layer based on mixed zinc tin oxide, having the formula Sn_{0,5}Zn_{0,5}O, having a resistivity of about 200 Ω·cm, with index n=1.99;
optionally an antireflection layer 65, which is a dielectric, based on zinc oxide, with index n=1.96, having a resistivity of about 0.01 Ω·cm, this layer being deposited here from a ceramic target directly on the blocking coating 50; then
optionally an antireflection layer 66 which is an absorption layer based on mixed zinc tin oxide, having the formula Sn_{0,5}Zn_{0,5}O, having a resistivity of about 200 Ω·cm, with index n=1.99.

It should be observed that the layers based on mixed zinc tin oxide over their whole thickness may have, over their thickness, Sn:Zn ratios which vary or percentages of doping agent which vary, according to the targets used to deposit these layers and in particular when several targets of different compositions are used to deposit a layer.

As for examples 1 to 3, these six electrode coatings were deposited on a clear glass substrate in order to constitute a front side of a photovoltaic panel, then a CdTe—CdS photovoltaic coating was deposited under the same conditions as for examples 1 to 3 on the front side TCO electrode coating of these examples 1 to 3, and finally, a non-transparent second electrode coating, based on gold, was deposited to form the rear side electrode of the photovoltaic panel, in the way shown in FIG. 2 (but without the rear side substrate 310, nor the resin layer as sometimes observed).

The conditions of deposition of these layers are known to a person skilled in the art because it concerns the production of stacks similar to those used for low-emissivity or solar-control applications.

In this respect, a person skilled in the art can refer to the patent applications EP 718 250, EP 847 965, EP 1 366 001, EP 1 412 300, or even EP 722 913.

It may be observed in particular that the stoichiometry of the layer based on mixed zinc tin oxide over its whole thickness may be different from that used here; however, it appears preferable to use only one amorphous or in any case incompletely crystalline layer and it appears preferable not to use a layer based on zinc stannate having the exact composition Zn₂SnO₄ (or optionally doped) because this material may have a particular crystallographic structure which is incompatible with the aim of resistance to the highly stressing heat treatment required by the present invention.

Furthermore, the layer based on mixed zinc tin oxide, when it forms the entire coating underlying the functional layer or the final layer of this coating, that is, in these two cases, when it is in contact with the photovoltaic material, serves to produce a smoothing layer, in particular when it is non-crystalline. Such a smoothing layer is particularly suitable when the photovoltaic material is based on cadmium.

Table 6 below shows the main characteristics of the photovoltaic panels thus produced on the basis of examples 4 to 10:

TABLE 6

| | Ex. 4 | Ex. 5 | Ex. 6 | Ex. 7 | Ex. 8 | Ex. 9 | Ex. 10 |
|---|---|---|---|---|---|---|---|
| R (Ω/□) | 9.5 | 10.6 | 7.6 | 8.1 | 7.6 | 8 | 10.4 |
| T_{L} (%) | 78.6 | 71.9 | 85.6 | 85.2 | 85.7 | 85.3 | 72.1 |
| R_{L} (%) | 19.1 | 27.7 | 3.6 | 4.1 | 22.5 | 28.7 | 27.5 |
| Abs (%) | 2.3 | 0.4 | 10.8 | 10.7 | 10.6 | 10.5 | 0.5 |
| Eta (%) | — | 9.3 | 8.3 | 9 | 9.3 | 7.5 | 9.3 |
| FF (%) | — | 63.5 | 61.3 | 63.2 | 64.5 | 57.8 | 64.6 |
| Jsc (mA/cm²) | — | 21.9 | 19.4 | 18.6 | 20.2 | 19.6 | 21.5 |
| Voc (V) | — | 0.66 | 0.73 | 0.73 | 0.72 | 0.66 | 0.67 |
| Rs (Ωcm²) | — | 5.3 | 8.1 | 7.2 | 7.5 | 8.6 | 6.1 |
| Rsh (kΩcm²) | — | 0.7 | 0.3 | 0.2 | 1.3 | 6 | 0.9 |

The top first four values in Table 6 were measured on the substrate alone, not coated with photovoltaic material and without heat treatment:
R is the resistance per square of the stack, measured with a four-point probe;

T_{L} is the light transmission in the visible, measured under illuminant D65;

R_{L} is the light reflection in the visible, measured under illuminant D65, substrate side;

Abs is the light absorption in the visible, measured under illuminant D65, substrate side.

The bottom last six values in this table were measured as previously for the first series of examples, after incorporation of the transparent electrode coating as the front side of a photovoltaic panel.

However, no value is given in this second part of the table for example 4 incorporated in a photovoltaic panel because these values were not measurable for this example. No production of electricity was observed.

To try to understand the reasons therefor, a TOF-SIMS analysis of the photovoltaic panel integrating example 4 was carried out.

The main parameters are summarized in the table below:

TABLE 7

| | | | Current | Area | Flux |
|---|---|---|---|---|---|
| | Ions | Energy (keV) | (nA) | (μm²) | (ions/cm²) |
| Sputtering | Cs⁺ | 2 | 130 | 300 × 300 | 1.91 × 10¹⁸ |
| Analysis | Bi³⁺ | 25 | 0.8 | 100 × 100 | 1.07 × 10¹⁴ |

FIG. 5 shows the results of this analysis with the time T per second plotted on the x-axis and the current I plotted on the y-axis measured for each element (in arbitrary units).

The analysis was carried out from the underside of the photovoltaic panel, that is the current peaks of the elements from left to right in FIG. 5 show the presence of elements respectively in the rear side electrode, in the photovoltaic material, and in the front side electrode.

Thus, the Cd peak in the middle of the figure (empty triangles) illustrates the presence of this element in the photovoltaic coating.

The peaks of Zn (empty circles) and Ag (solid stars) at the right of the figure show the presence of these elements in the front side electrode coating.

However, in this figure, a peak of Ag may also be observed in the left of the figure.

This peak is abnormal because neither the rear side electrode coating nor the photovoltaic coating comprises silver.

This therefore probably represents a migration of silver from the functional layer 40 of the front side electrode coating through the photovoltaic material.

This migration can explain the fact that the photovoltaic panel incorporating example 4 finally failed to produce electricity; the front side electrode coating is probably no longer sufficiently conducting although the electrode coating as deposited normally comprises sufficient silver to allow the passage of current.

The examples according to the invention 5 to 9 served to obtain photovoltaic panel parameters substantially identical to those obtained in the context of example 3 with the TCO front side electrode.

In particular, it was observed that:
the quantum efficiency Eta was better than with TCO;
the fill factor FF was better than with TCO;
the short-circuit current Jsc was as good as with TCO;
the open-circuit voltage Voc was as good as with TCO;
the series resistance Rs was as good as with TCO, or even better (case of example 5) and
the shunt resistance Rsh was sometimes as good as with TCO; sometimes not as good (example 9).

A TOF-SIMS analysis of the photovoltaic panel integrating examples 5 and 9 was carried out.

The main parameters are summarized in the table:

TABLE 8

| | | Energy | Current | Area |
|---|---|---|---|---|
| | Ions | (keV) | (nA) | (μm²) |
| Sputtering | Cs⁺ | 5 | 30 | 150 × 150 |
| Analysis | Ga⁺ | 15 | inconnu | 30 × 30 |

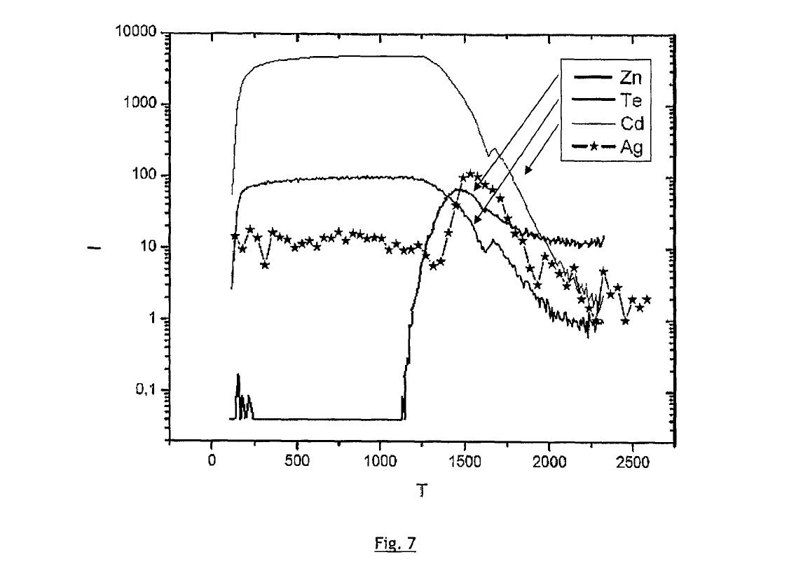

FIGS. 6 and 7 show the results of these two analyses, respectively for the panel incorporating example 5 and for the panel incorporating example 9 with the time T per second plotted on the x-axis and the current I plotted on the y-axis measured for each element (in arbitrary units, but comparable from one analysis to the other).

As for example 4, the analysis was carried out from the underside of the photovoltaic panel, that is the current peaks of the elements from left to right in FIGS. 6 and 7 show the presence of elements respectively in the rear side electrode, in the photovoltaic material, and in the front side electrode.

Unlike what was observed in FIG. 5, there is no longer any silver peak on the left of FIGS. 6 and 7.

The mechanism of silver migration from the functional layer 40 was therefore prevented by the presence of the layer 62 based on mixed zinc tin oxide, and also probably, but to a lesser degree, by the presence of the layer 66 based on mixed zinc tin oxide (example 9).

The TOF-SIMS profiles of examples 6 to 8 serve to make exactly the same observations as respectively for examples 5 and 9: there is no longer any silver peak on the left.

For examples 5 to 9, it should be observed that the optical thickness of the coating 20 below the metal functional layer is about 88 nm (=30×1.99+7×1.99+7×1.96) and that the total thickness of the layer based on mixed zinc tin oxide 62 (+optionally 66) above the metal functional layer is about:
for example 5: 240 nm (=120×1.99);
for example 6: 10 nm (=5×1.99);
for example 7: 40 nm (=20×1.99);
for example 8: 20 nm (=5×1.99+5×1.99);
for example 9: 40 nm (=10×1.99+10×1.99).

For example 5, the layer based on mixed zinc tin oxide 62 thus has an optical thickness equal to 2.7 times the optical thickness of the antireflection coating 20 and for examples 6 to 9, the total of the layer(s) based on mixed zinc tin oxide 62 (+66) present and an optical thickness of between 0.1 and 0.45 times the optical thickness of the antireflection coating 20.

For example 10, the optical thickness of the coating 20 below the metal functional layer is about 60 nm (=20×1.99+5×1.99+5×1.96) and the total thickness of the layer based on mixed zinc tin oxide 62 above the metal functional layer is about 219 nm (=110×1.99). For example 10, the layer based on mixed zinc tin oxide 62 thus has an optical thickness equal to 3.65 times the optical thickness of the antireflection coating 20.

Furthermore, for these examples 6 to 9, the total of the layer(s) based on mixed zinc tin oxide 62 (+66) represents between 3.8% and 16.9% of the optical thickness of the antireflection coating 60.

Moreover, it is advantageous to observe that the stacks of thin layers forming the electrode coating in the context of the invention do not necessarily have a very high transparency in absolute terms.

Thus, in the case of example 5, the light transmission in the visible of the substrate coated only with the stack forming the electrode coating and without the photovoltaic material is about 72% before any heat treatment.

The stacks of thin layers forming the electrode coating according to the invention may undergo the etching steps usually applied to the cells in order to integrate them into photovoltaic panels.

The present invention has been described above as an example. It is understood that a person skilled in the art is capable of obtaining different variants of the invention while remaining within the scope of the patent as defined by the claims.

1. A photovoltaic panel, comprising:
an absorbent photovoltaic material, and
a front side substrate
wherein the front side substrate comprises, on a main surface, a transparent electrode coating comprising a stack of thin layers comprising at least one metal functional layer, and at least a first and second antireflection coating,
wherein the antireflection coatings each comprise at least one antireflection layer,
wherein the at least one metal functional layer is placed between the first and second antireflection coatings, and
wherein the antireflection coating is placed above the metal functional layer opposite the substrate, and comprises a single antireflection layer comprising mixed zinc tin oxide over its whole thickness, the antireflection layer comprising mixed zinc tin oxide having an optical thickness of between 1.5 and 4.5 times, inclusive, the optical thickness of the first antireflection coating placed below the metal functional layer.

2. A photovoltaic panel, comprising:
an absorbent photovoltaic material; and
a front side substrate wherein the front side substrate comprises, on a main surface, a transparent electrode coating comprising a stack of thin layers comprising at least one metal functional layer and at least a first and second antireflection coatings,
wherein the antireflection coatings each comprise at least one antireflection layer,
wherein the at least one metal functional layer is placed between the first and second antireflection coatings,
wherein the second antireflection coating is placed above the metal functional layer opposite the substrate and comprises at least a first and a second antireflection layer comprising,
wherein the first antireflection layer is closer to the functional layer and comprises mixed zinc tin oxide over its whole thickness, and
wherein the second antireflection layer is further from the at least one metal functional layer and does not comprise mixed zinc tin oxide over its whole thickness, and
wherein the first antireflection layer comprising mixed zinc tin oxide has an optical thickness of between 0.1 and 6 times, inclusive, the optical thickness of the first antireflection coating placed below the metal functional layer.

3. The photovoltaic panel of claim 2, wherein the second antireflection layer comprises zinc oxide over its whole thickness.

4. The photovoltaic panel of claim 2, wherein the at least one first antireflection layer comprising mixed zinc tin oxide over its whole thickness, has a total optical thickness representing between 2 and 50% of the optical thickness of the second antireflection coating farthest from the substrate.

5. The photovoltaic panel of claim 2, wherein the at least one first antireflection layer comprising mixed zinc tin oxide over its whole thickness, has a total optical thickness representing between 50 and 95% of the optical thickness of the antireflection coating farthest from the substrate.

6. The photovoltaic panel of claim 1, wherein the antireflection layer comprising mixed zinc tin oxide over its whole thickness, has a resistivity ρ of between 2.10⁻⁴ Ω·cm and 10⁵ Ω·cm.

7. The photovoltaic panel of claim 1, wherein the second antireflection coating placed above the metal functional layer has an optical thickness of between 0.4 and 0.6 times a maximum absorption wavelength λₘ of the photovoltaic material, inclusive.

8. The photovoltaic panel of claim 1, wherein the second antireflection coating placed above the metal functional layer has an optical thickness of between 0.075 and 0.175 times a maximum absorption wavelength λₘ of the photovoltaic material, inclusive.

9. The photovoltaic panel of claim 1, wherein the substrate comprises, under the electrode coating, a base antireflection layer having a low refractive index n₁₅ close to that of the substrate.

10. The photovoltaic panel of claim 1, wherein the functional layer is deposited above a wetting layer on comprising oxide, optionally doped.

11. The photovoltaic panel claim 1, wherein the functional layer is placed in at least one location selected from the group consisting of directly on at least one underlying blocking coating and directly under at least one overlying blocking coating.

12. The photovoltaic panel of claim 11, further comprising at least one blocking coating Ni or Ti or a Ni comprising alloy.

13. The photovoltaic panel of claim 1, wherein the first antireflective coating under the metal functional layer towards the substrate comprises a layer comprising mixed oxide.

14. The photovoltaic panel of claim 1, wherein at least one selected from the group consisting of
the first antireflective coating under the metal functional layer towards the substrate and
the second antireflective coating above the metal functional layer,
comprises a layer with a very high refractive index.

15. The photovoltaic panel of claim 1, wherein the electrode coating comprises a stack suitable for architectural glazing.

16. A substrate, comprising a coating with a stack of thin layers for the photovoltaic panel of claim 1.

17. The substrate of claim 16, further comprising a coating comprising a photovoltaic material above the electrode coating opposite the front side substrate.

18. A method of preparing a front side substrate of the photovoltaic panel of claim 1, the method comprising
coating the substrate with the stack of thin layers.

19. The method of claim 18, wherein the substrate comprising the electrode coating is suitable for architectural glazing.

20. The photovoltaic panel of claim 2, wherein the at least one first antireflection layer comprising mixed zinc tin oxide over its whole thickness, has a total optical thickness representing between 3 and 30% of the optical thickness of the second antireflection coating farthest from the substrate.
